(19) United States
(12) Patent Application Publication
(10) Pub. No.: US 2005/0258505 A1
(43) Pub. Date: Nov. 24, 2005

(54) Mixed implantation on polysilicon fuse for CMOS technology

(75) Inventors: Juing-Yi Wu, Hsinchu City (TW); Tong-Chern Ong, Chong-Her City (TW); Chin-Shan Hou, Hsin-Chu City (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co., Ltd.

(21) Appl. No.: 10/851,043

(22) Filed: May 20, 2004

(51) Int. Cl. H01L 21/82; H01L 29/00

(52) U.S. Cl. 257/529; 438/132

(57) ABSTRACT

A programmable fuse device includes a polysilicon layer having a mixed ion implantation disposed on a silicon substrate. The polysilicon layer includes at least one first region having a first type ion implantation and at least one second region having a second type ion implantation opposite to the first type. Each of the first and second regions are disposed adjacently to form a corresponding polysilicon junction having a junction resistance. A silicide layer is disposed on the polysilicon layer. A predefined voltage potential is applied across the silicide layer for programming the device. This causes a flow of current through the silicide layer, which generates sufficient heat to cause an agglomeration in the silicide layer. The agglomeration causes at least one junction resistance to be included in series with the flow of current after the programming.

### BACKGROUND

The present invention relates generally to integrated circuit (IC) devices, and more particularly, to fusible link devices used in complementary metal oxide semiconductor (CMOS) integrated circuits.

IC's are generally manufactured with internal connections that are set during the manufacturing process. However, due to high development costs, lengthy lead times, and the high tooling costs of these IC's, many users prefer circuits which may be programmed after being manufactured such as in the field. These IC's are typically referred to as programmable circuits since they usually contain programmable links. In general, programmable links are electrical interconnects which may be opened or closed at predefined electronic elements by a user in order to activate or deactivate the predefined electronic elements.

A well-known example of an IC deploying programmable links is a programmable read-only memory (PROM). A common form of programmable link is a fusible link. To ‘program’ the PROM, the fusible link is blown or opened at predefined electronic nodes to create an open circuit. The combination of blown and unblown fusible links constitutes a digital bit pattern of ones and zeros, which is representative of the data stored in the PROM by the user. In some applications, fusible links maybe used to program redundant electronic elements such as transistors to replace identical defective elements during and/or after the manufacturing process.

Fuse devices typically include polysilicon (poly) fuses and/or metal fuses. A known problem with metal fuses is the (lack of) integrity of the open circuit created by the blown metal fuse. The use of polysilicon fuses has been growing to overcome some of the known problems associated with the metal fuses. Specifically, the polysilicon fuse typically vaporizes when blown.

A typical structure of a polysilicon fuse device 100, according to the prior art is shown in FIG. 1. A polysilicon layer 110 is formed on a silicon substrate (not shown). In some cases, the polysilicon layer 110 may be formed on an oxide layer (not shown) above the silicon substrate. The polysilicon layer 110 is typically doped with one type of semiconductor material, such as N+ type material or preferably P+ type. As described herein, the concentrations of doping are denoted by N+ and N− for n-doped material (n-material), and by P+ and P− for p-doped material (p-material).

The size and shape of the polysilicon layer 110 shown substantially resembles a rectangular prism having a length L 112, a height H 114 and a depth D 116. The approximate L×H×D dimensions are 20,000×1800×1000 Angstroms. Sheet resistance of the P+ polysilicon layer 110 is approximately 100˜2000 ohms/sq. A silicide layer 120 is formed on the polysilicon layer 110. Well-known silicides such as cobalt, titanium, tungsten, tantalum or platinum suicides may be used to form the silicide layer 120. The sheet resistance of the silicide layer 120 generally depends on its composition, but is approximately 1˜50 ohm/sq, which is much less than the polysilicon layer 110. A pair of contacts 130 provide electrical coupling for the polysilicon fuse device 100.

To program the polysilicon fuse device 100 a predetermined voltage potential is applied across the pair of contacts 130. The application of the voltage potential causes a current to flow through the polysilicon fuse device 100, and thereby generate heat. Direction of the flow of electrons 122 is shown, which is opposite to that of the flow of the current. Due to the lower sheet resistance of the silicide layer 120 a majority of the current flows through the silicide layer 120 in comparison to the polysilicon layer 110. The heat generated by the current flowing through the silicide layer 120 causes an agglomeration (not shown), which causes the sheet resistance of the silicide layer 120 to change abruptly. Thus, in the blown or programmed state the polysilicon fuse device 100 has a much higher resistance (ideally an open circuit) due to the presence of the polysilicon layer 110 compared to an unprogrammed state. In other words, the programming of the polysilicon fuse device 100 causes its basic resistivity to change.

Presently, however, a typical predetermined voltage potential needed to program the polysilicon fuse device 100 is often too high. Higher applied voltages for programming the polysilicon fuse device 100 may tend to cause damage to the IC. In addition, the resistance of some of the P+ type polysilicon fuse devices may not be sufficiently high after programming.

Thus, a need exists to provide an improved polysilicon fuse device that is programmable with a reduced voltage potential. In addition, a need exists to increase the resistance of the fuse device after programming. Furthermore, a need exists to manufacture the improved polysilicon fuse device without making substantial changes to the manufacturing process for making IC's.

### SUMMARY OF THE INVENTION

The problems outlined above are addressed in a large part by an apparatus and method for improving polysilicon fuse devices, as described herein. According to one form of the invention, a programmable fuse device includes a polysilicon layer having a mixed ion implantation disposed on a silicon substrate. The polysilicon layer includes at least one first region having a first type ion implantation and at least one second region having a second type ion implantation opposite to the first type. Each of the first and second regions are disposed adjacently to form a corresponding polysilicon junction having a junction resistance. A silicide layer is disposed on the polysilicon layer. A predefined voltage potential is applied across the silicide layer for programming the device. This causes a flow of current through the silicide layer, which generates sufficient heat to cause an agglomeration in the silicide layer. The agglomeration causes at least one junction resistance to be included in series with the flow of current after the programming.

According to another aspect of the invention, the method for increased resistance of a programmable fuse device after programming includes forming a polysilicon layer on a semiconductor substrate. At least one first region having a first type ion implantation and at least one second region having a second type ion implantation opposite to the first type are formed in the polysilicon layer. Each of the first and second regions are disposed adjacently to form a corresponding polysilicon junction having a junction resistance. A silicide layer is formed on the polysilicon layer and a predefined voltage potential is applied across the silicide layer for the programming. This causes a flow of current to through the silicide layer, thereby generating sufficient heat to cause an agglomeration in the silicide layer. The agglomeration causes at least one junction resistance to be included in series with the flow of current after the programming.

Other forms, as well as objects and advantages of the invention will become apparent upon reading the following detailed description and upon reference to the accompanying drawings.

### BRIEF DESCRIPTION OF THE DRAWINGS

Novel features believed characteristic of the invention are set forth in the appended claims. The invention itself, however, as well as a preferred mode of use, various objectives and advantages thereof, will best be understood by reference to the following detailed description of an illustrative embodiment when read in conjunction with the accompanying drawings.

FIG. 1 is an illustrative diagram of a traditional polysilicon fuse device, described herein above, according to prior art.

FIG. 2 is an illustrative diagram of an improved polysilicon fuse device, according to an embodiment.

FIG. 3 illustrates, in a tabular form, electrical characteristics of polysilicon fuse devices of FIG. 1 and FIG. 2, according to an embodiment.

FIG. 4 illustrates, in a graphical form, electrical characteristics of polysilicon fuse devices of FIG. 1 and FIG. 2, according to an embodiment.

FIG. 5 is a flow chart illustrating a method for increased resistance of a programmable fuse device of FIG. 2 after programming, according to an embodiment.

### DETAILED DESCRIPTION OF AN EMBODIMENT

While the invention is susceptible to various modifications and alternative forms, specific embodiments thereof are shown by way of example in the drawings and will be described herein in detail. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

Elements, which appear in more than one figure herein, are numbered alike in the various figures. The present invention describes an apparatus and method to improve performance of a LDMOS device. According to one form of the invention, a programmable fuse device includes a polysilicon layer having a mixed ion implantation disposed on a silicon substrate. The polysilicon layer includes at least one first region having a first type ion implantation and at least one second region having a second type ion implantation opposite to the first type. Each of the first and second regions are disposed adjacently to form a corresponding polysilicon junction having a junction resistance. A silicide layer is disposed on the polysilicon layer. A predefined voltage potential is applied across the silicide layer for programming the device. This causes a flow of current through the silicide layer, which generates sufficient heat to cause an agglomeration in the silicide layer. The agglomeration causes at least one junction resistance to be included in series with the flow of current after the programming.

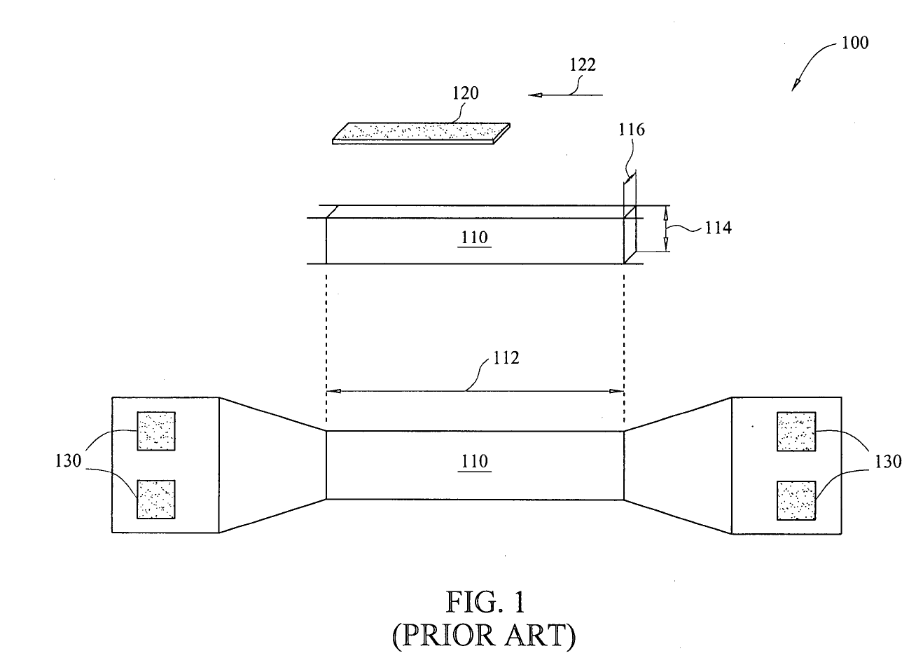

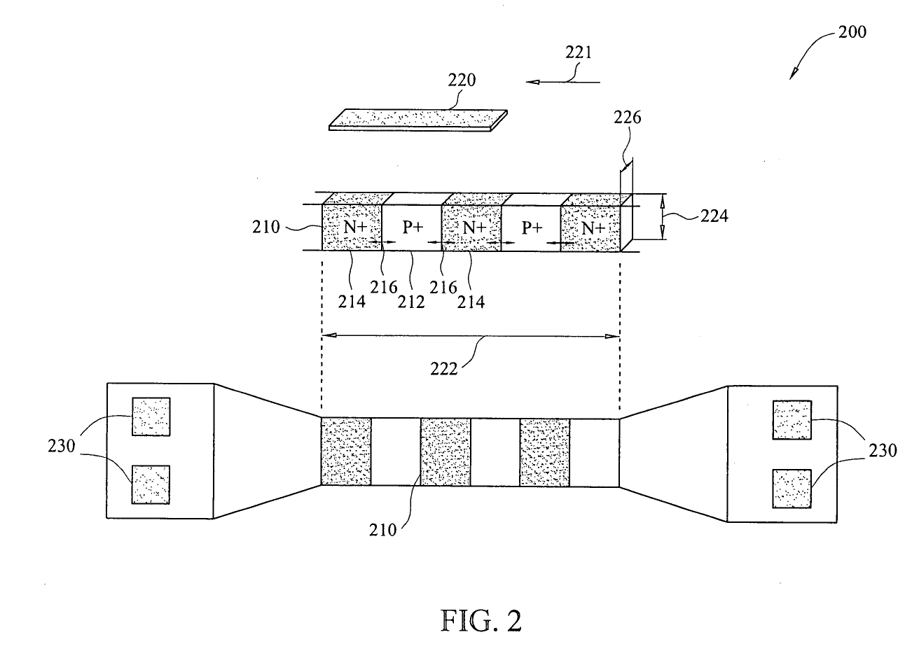

FIG. 2 is an illustrative diagram of an improved polysilicon fuse device 200, according to an embodiment. A polysilicon layer 210 is formed on a silicon substrate (not shown). In some cases, the polysilicon layer 210 may be formed on an oxide layer (not shown) above the silicon substrate. The polysilicon layer 210 is formed by a mixed implantation of a first type doping material, e.g., P+ type, in a first region 212 and a second type of doping material opposite to the first type, e.g., N+ type, in a second region 214. Each of the first and second regions 212 and 214 are disposed adjacently to form a corresponding polysilicon junction 216 having a junction resistance. Due to the presence of polysilicon junctions 216 between the first and second implantation regions 212 and 214, the resistance of the mixed implantation is advantageously increased compared to the polysilicon fuse device 100 of FIG. 1.

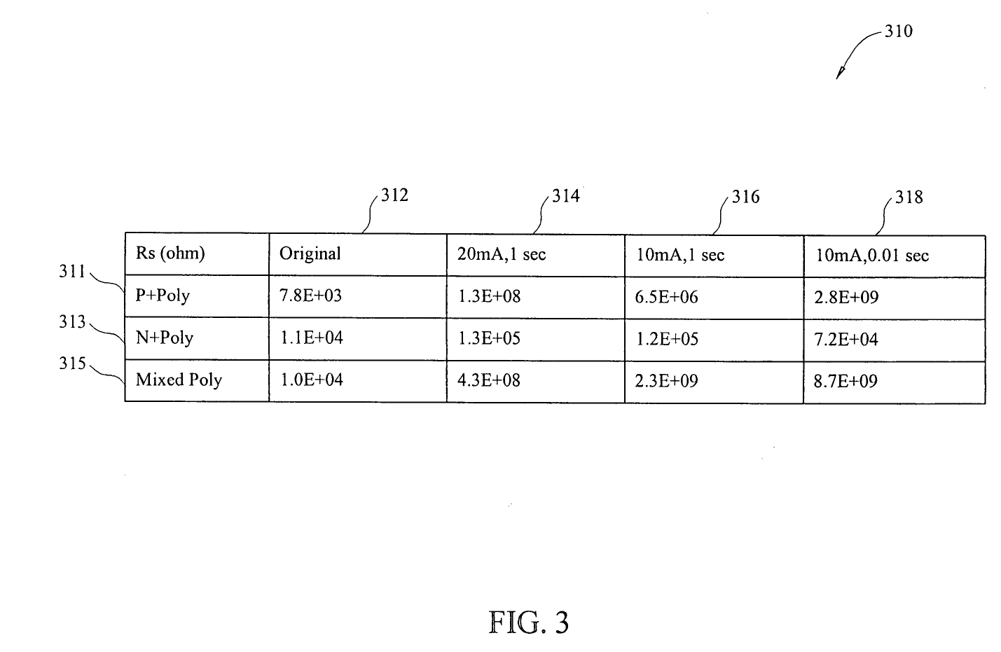

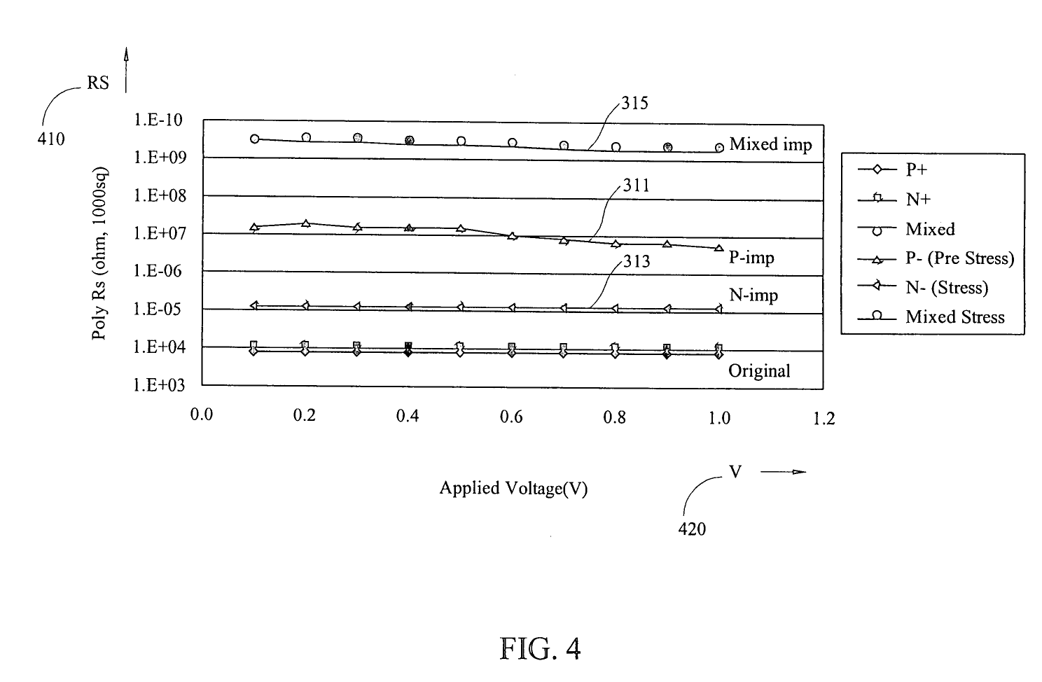

The size and shape of the polysilicon layer 210 shown substantially resembles a rectangular prism having a length L 222, a height H 224 and a depth D 226. The approximate L×H×D dimensions are 20,000×1800×1000 Angstroms. In one embodiment, the first and second regions 212 and 214 have substantially similar dimensions. The approximate dimensions of each of the first and second regions 212 and 214 are 3000×1800×1000 Angstroms. The polysilicon fuse device 200 may include about 8 to 10 squares of the first and second regions 212 and 214. Sheet resistance of the mixed implantation polysilicon layer 210 is approximately 1,000 times higher compared to the polysilicon layer 110 having one type of implantation. Additional detail of the resistive characteristics the polysilicon fuse devices 100 and 200 are described in FIGS. 3 and 4.

A silicide layer 220 is formed on the mixed implantation polysilicon layer 210. Well-known suicides such as cobalt, titanium, tungsten, tantalum or platinum silicides may be used to form the silicide layer 220. The sheet resistance of the silicide layer 220 generally depends on its composition, but is approximately 1˜50 ohm/sq, which is much less than the mixed polysilicon layer 210. A pair of contacts 230 provide electrical coupling for the polysilicon fuse device 200.

To program the polysilicon fuse device 200 a predetermined voltage potential is applied across the pair of contacts 230. In one embodiment, the predetermined voltage potential may vary between approximately ±2V and approximately ±4V. The application of the voltage potential causes a current to flow through the polysilicon fuse device 200, and thereby generate heat. In the depicted embodiment, direction of the flow of electrons 221 is shown, which is opposite to that of the flow of the current. Due to the lower sheet resistance of the silicide layer 220 a majority of the current flows through the silicide layer 220 in comparison to the mixed polysilicon layer 210. The heat generated by the current flowing through the silicide layer 220 causes an agglomeration (not shown), which causes the sheet resistance of the silicide layer 220 to change abruptly. Thus, in the blown or programmed state the polysilicon fuse device 200 has a much higher resistance due to the introduction of at least one of the junction resistances in the path of the current, compared to an unprogrammed state. In other words, the programming of the polysilicon fuse device 200 causes its basic resistivity to change.

In one embodiment, the polysilicon layer 210 having the mixed implantation is added during the manufacturing process for the polysilicon fuse device 200, which is substantially similar to the manufacturing process for the polysilicon fuse device 100. Thus, the mixed implantation polysilicon layer 210 is advantageously added without substantially changing the manufacturing process used for manufacturing the polysilicon fuse device 100, which has only one type of ion implantation. That is, no additional masks and/or ion implantation steps need to be added to advantageously increase the after programming resistance of the polysilicon fuse device 200. In one embodiment, only two implantation masks used with the manufacturing process for the polysilicon fuse device 100 are to be modified to manufacture the mixed implantation polysilicon fuse device 200. Implementing the polysilicon fuse device 200 without additional or extra masks and/or processing steps also advantageously contributes to its low cost.

An experiment was performed to measure the electrical characteristics of the traditional polysilicon fuse device 100 of FIG. 1 and the electrical characteristics of the improved polysilicon fuse device 200 of FIG. 2.

Shown within FIG. 3 and FIG. 4 are results of the experiment, which illustrate the electrical characteristics of the two polysilicon fuse devices 100 and 200. FIG. 3 illustrates, in a tabular form, exemplary sheet resistance levels for various ion implantations in polysilicon layer measured under various current stress conditions, according to one embodiment. In the depicted embodiment, the L×W of the polysilicon layer is approximately 100×0.1 microns. In this embodiment, table T1 310 illustrates exemplary sheet resistances levels under various stress conditions (columns) and implantation types (rows). Shown in the columns are original 312 (e.g., without current stress condition), first stress condition 314, second stress condition 316 and third stress condition 318, and shown in rows are a P+ 311 implantation used in the polysilicon layer 110, an N+ implantation 313 and a mixed implantation 315 used in the polysilicon layer 210. The effect of the mixed implantation 315 on the polysilicon fuse device 200 is illustrated by comparing resistance values in the rows corresponding to the mixed implantation 315 and the P+ 311 implantation. The values illustrate that the mixed implantation 315 provides significant increase in the after programming resistance of the polysilicon fuse device 200.

The effect of the mixed implantation 315 versus one type of implantation on the sheet resistance is shown in FIG. 4, according to one embodiment. In the depicted embodiment, shown in FIG. 4 is a plot of a sheet resistance RS 410 (on Y axis) versus applied voltage V 420 (on X axis) for P+ implantation 311, N+ implantation 313, mixed implantation 315 under stress condition and under original condition. In the depicted embodiment, a value for the applied voltage V 420 varies between approximately 0.1V and 1V.

As is illustrated by table T1 310 of FIG. 3 and comparison plot of FIG. 4, the sheet resistance RS 410 for mixed implantation 315 deployed in the polysilicon device 200 is advantageously increased by a factor of at least 1,000 when compared to a single type P+ implantation 311 deployed in the polysilicon device 100.

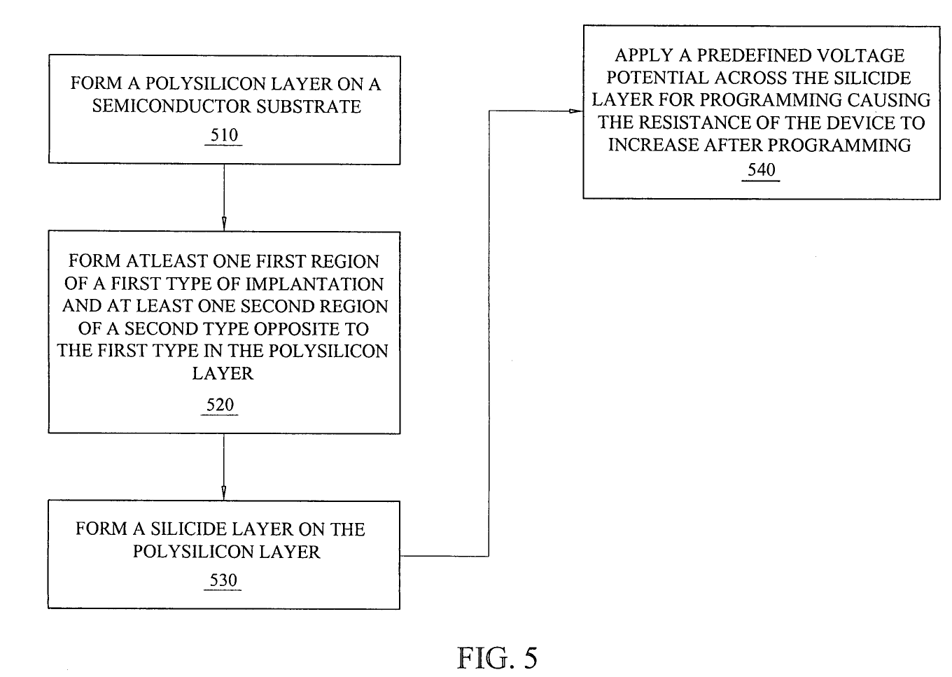

FIG. 5 is a flow chart illustrating a method for increased resistance of a programmable fuse device such as the polysilicon fuse device 200 after programming, according to one embodiment. In step 510, the polysilicon layer 210 is formed on a semiconductor substrate. In step 520, at least one first region (e.g., first region 212) having a first type ion implantation (e.g., P+ implantation) and at least one second region (e.g., second region 214) having a second type ion implantation opposite to the first type (e.g., N+ type) is formed in the polysilicon layer 210. Each of the first and second regions 212 and 214 are disposed adjacently to form a corresponding polysilicon junction 216 having a junction resistance. In step 530, a the silicide layer 220 is formed on the polysilicon layer 210. In step 540, a predefined voltage potential is applied across the silicide layer 220 for programming. The application of the predefined voltage potential causes a flow of current through the silicide layer 220. The flow of current generates sufficient heat to cause an agglomeration in the silicide layer 220. The agglomeration causes at least one junction resistance 216 to be included in series with the flow of current after the programming. Various steps of FIG. 5 may be added, omitted, combined, altered, or performed in different orders.

Although the embodiments above have been described in considerable detail, numerous variations and modifications will become apparent to those skilled in the art once the above disclosure is fully appreciated. It is intended that the following claims be interpreted to embrace all such variations and modifications.

1. A programmable fuse device comprising:
a polysilicon layer disposed on a silicon substrate, the polysilicon layer including at least one first region having a first type ion implantation and at least one second region having a second type ion implantation opposite to the first type, wherein each of the first and second regions are disposed adjacently to form a corresponding polysilicon junction having a junction resistance; and
a silicide layer disposed on the polysilicon layer, wherein a predefined voltage potential applied across the silicide layer for programming causes a flow of current through the silicide layer, wherein the flow of current generates sufficient heat to cause an agglomeration in the silicide layer, wherein the agglomeration causes at least one junction resistance to be included in series with the flow of current after the programming.

2. The device of claim 1, wherein the predefined voltage potential is varied between approximately ±2V and approximately ±4V.

3. The device of claim 1, wherein the at least one junction resistance is at least 1000 times higher compared to a polysilicon layer having one type of implantation.

4. The device of claim 1, wherein a first manufacturing process for manufacturing the device is substantially similar to a second manufacturing process for manufacturing the device without the polysilicon junction.

5. The device of claim 4, wherein resistance after the programming of the device is increased without adding an extra mask step to the second manufacturing process.

6. The device of claim 4, wherein resistance after the programming of the device is increased without adding an extra ion implantation step to the second manufacturing process.

7. The device of claim 4, wherein the first manufacturing process uses two modified ion implantation masks compared to the second manufacturing process.

8. The device of claim 1, wherein the first type ion implantation is a P+ type and the second type ion implantation is an N+ type.

9. The device of claim 1, wherein dimensions of each of the first and second regions are substantially similar.

10. The device of claim 1, wherein the silicide layer includes cobalt silicide.

11. A method for increased resistance of a programmable fuse device after programming, the method comprising:
forming a polysilicon layer on a semiconductor substrate;
forming at least one first region having a first type ion implantation and at least one second region having a second type ion implantation opposite to the first type in the polysilicon layer, wherein each of the first and second regions are disposed adjacently to form a corresponding polysilicon junction having a junction resistance;
forming a silicide layer disposed on the polysilicon layer; and
applying a predefined voltage potential across the silicide layer for the programming to cause a flow of current through the silicide layer, wherein the flow of current generates sufficient heat to cause an agglomeration in the silicide layer, wherein the agglomeration causes at least one junction resistance to be included in series with the flow of current after the programming.

12. The method of claim 11, wherein the predefined voltage potential is varied between approximately ±2V and approximately ±4V.

13. The method of claim 11, wherein the at least one junction resistance is at least 1,000 times higher compared to a polysilicon layer having one type of implantation.

14. The method of claim 11, wherein a first manufacturing process for manufacturing the device is substantially similar to a second manufacturing process for manufacturing the device without the at least one polysilicon junction.

15. The method of claim 14, wherein resistance after the programming of the device is increased without adding an extra mask step to the second manufacturing process.

16. The method of claim 14, wherein resistance after the programming of the device is increased without adding an extra ion implantation step to the second manufacturing process.

17. The method of claim 14, wherein the first type ion implantation is a P+ type and the second type ion implantation is an N+ type.

18. The method of claim 11, wherein the dimensions of each of the first and second regions are substantially similar.

19. The method of claim 11, wherein the silicide layer includes cobalt silicide.
